(19) United States
(12) Patent Application Publication
(10) Pub. No.: US 2023/0096770 A1
(43) Pub. Date: Mar. 30, 2023

(54) METHOD FOR MANUFACTURING METAL-CLAD LAMINATE, AND METAL-CLAD LAMINATE

(71) Applicant: Panasonic Intellectual Property Management Co., Ltd., Osaka (JP)

(72) Inventors: Yusuke ITO, Mie (JP); Masaya KOYAMA, Mie (JP)

(73) Assignee: Panasonic Intellectual Property Management Co., Ltd., Osaka (JP)

(21) Appl. No.: 17/801,731

(22) PCT Filed: Feb. 22, 2021
(86) PCT No.: PCT/JP2021/006673

§ 371 Date: Aug. 23, 2022

(30) Foreign Application Priority Data
Feb. 25, 2020 (JP) 2020-029834

(51) Int. Cl. B32B 15/08; H05K 1/05; H05K 3/38; B32B 27/08; B32B 7/02

(52) U.S. Cl. CPC B32B 15/08; H05K 1/05; H05K 3/38; B32B 27/08; B32B 7/02; H05K 2201/0141; B32B 15/20

(57) ABSTRACT

A manufacturing method includes stacking, between two endless belts, a first sheet of metal foil, a plurality of insulating films, and a second sheet of metal foil in this order one on top of another and hot-press molding these sheets and films together to form an insulating layer out of the plurality of insulating films. Each of the plurality of insulating films has a first surface and a second surface. The second surface has a larger ten-point mean roughness (Rzjis) than the first surface. The absolute value of difference between a ten-point mean roughness (Rzjis) of a surface, in contact with the first sheet of metal foil, of the insulating layer and a ten-point mean roughness (Rzjis) of another surface, in contact with the second sheet of metal foil, of the insulating layer is equal to or less than 0.35 μm.

### TECHNICAL FIELD

The present disclosure relates to a method for manufacturing a metal-clad laminate and a metal-clad laminate.

### BACKGROUND ART

A metal-clad laminate, including an insulating layer containing a thermoplastic resin and a sheet of metal foil laid on top of the insulating layer, has been used as a material for a printed wiring board such as a flexible printed wiring board. A liquid crystal polymer is one of various materials for the insulating layer (see Patent Literature 1). The liquid crystal polymer has the advantage of enabling imparting good RF characteristics to a printed wiring board formed out of a metal-clad laminate.

### CITATION LIST

### Patent Literature

Patent Literature 1: JP 2010-221694 A

### SUMMARY OF INVENTION

The problem to be overcome by the present disclosure is to provide a method for manufacturing a metal-clad laminate and a metal-clad laminate, both of which make it easier to increase the thickness of an insulating layer and reduce the chances of causing a decline in the peel strength of a sheet of metal foil with respect to the insulating layer.

A method for manufacturing a metal-clad laminate according to an aspect of the present disclosure includes: continuously feeding, to between two endless belts, a first sheet of metal foil, a plurality of insulating films, and a second sheet of metal foil different from the first sheet of metal foil; and stacking, between the endless belts, the first sheet of metal foil, the plurality of insulating films, and the second sheet of metal foil in this order one on top of another and hot-press molding the first sheet of metal foil, the plurality of insulating films, and the second sheet of metal foil together to form an insulating layer out of the plurality of insulating films. Each of the plurality of insulating films has a first surface and a second surface opposite from the first surface. The second surface has a larger ten-point mean roughness (Rzjis) than the first surface. The absolute value of difference between a ten-point mean roughness (Rzjis) of a surface, in contact with the first sheet of metal foil, of the insulating layer and a ten-point mean roughness (Rzjis) of another surface, in contact with the second sheet of metal foil, of the insulating layer is equal to or less than 0.35 μm.

A metal-clad laminate according to another aspect of the present disclosure includes: an insulating layer; and a sheet of metal foil laid on top of the insulating layer. The insulating layer includes a plurality of resin layers. The insulating layer has a thickness equal to or greater than 100 μm and equal to or less than 300 μm. The resin layers each contain a liquid crystal polymer. A peel strength of the sheet of metal foil with respect to the insulating layer is equal to or greater than 0.60 N/mm

### BRIEF DESCRIPTION OF DRAWINGS

FIG. 1 is a schematic representation illustrating a manufacturing process of a metal-clad laminate according to a first embodiment of the present disclosure;

FIG. 2 is a schematic cross-sectional view of either a metal-clad laminate according to a second embodiment of the present disclosure or a metal-clad laminate manufactured by a manufacturing method according to the first embodiment of the present disclosure;

FIG. 3A is a schematic cross-sectional view of a stack in a manufacturing process of a metal-clad laminate in a situation where only one insulating film is used;

FIG. 3B is a schematic cross-sectional view of a metal-clad laminate and endless belts in the manufacturing process of the metal-clad laminate in the situation where only one insulating film is used;

FIG. 4A is a schematic cross-sectional view of a stack in the manufacturing process shown in FIG. 1; and

FIG. 4B is a schematic cross-sectional view of a metal-clad laminate and endless belts in the manufacturing process shown in FIG. 1.

### DESCRIPTION OF EMBODIMENTS

To improve the stability of the RF characteristics of a printed wiring board, the present inventors attempted to increase the thickness of an insulating layer included in the printed wiring board.

As a result of research and development, the present inventors discovered that an insulating film such as a liquid crystal polymer film having a thickness greater than 100 μm was not only rarely available because of difficulty to make such a thick insulating film but also could cause a decline in the stability of the performance of the printed wiring board. In particular, the present inventors discovered that such a thick insulating film tended to cause a decline in the peel strength of a sheet of metal foil with respect to the insulating layer.

Thus, the present inventors conducted extensive research and development to provide a method for manufacturing a metal-clad laminate and a metal-clad laminate, both of which would make it easier to increase the thickness of the insulating layer and reduce the chances of causing a decline in the peel strength of the sheet of metal foil with respect to the insulating layer, thus conceiving the concept of the present disclosure.

An exemplary embodiment of the present disclosure will now be described. Note that the embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

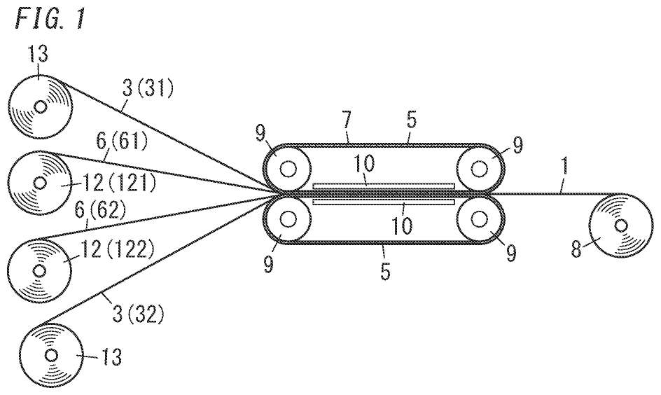

A method for manufacturing a metal-clad laminate 1 according to a first embodiment will be described. In the manufacturing method according to this embodiment, a first sheet of metal foil 31, a plurality of insulating films 6, and a second sheet of metal foil 32 different from the first sheet of metal foil 31 are continuously fed to between two endless belts 5 as shown in FIG. 1. Between the endless belts 5, the first sheet of metal foil 31, the plurality of insulating films 6, and the second sheet of metal foil 32 are stacked in this order one on top of another and subjected to hot-press molding, thereby forming an insulating layer 2 out of the plurality of insulating films 6. Each of the plurality of insulating films 6 has a first surface 601 and a second surface 602 opposite from the first surface 601. The second surface 602 has a larger ten-point mean roughness (Rzjis) than the first surface 601. The absolute value of the difference between the ten-point mean roughness (Rzjis) of a surface 401, in contact with the first sheet of metal foil 31, of the insulating layer 2 and the ten-point mean roughness (Rzjis) of another surface 402, in contact with the second sheet of metal foil 32, of the insulating layer 2 is equal to or less than 0.35 μm.

According to this embodiment, the insulating layer 2 is formed out of the plurality of insulating films 6, thus making it easier to increase the thickness of the insulating layer 2. Thickening the insulating layer 2 may reduce the chances of transmission loss being caused by electrostatic capacitance and leaking resistance between respective parts of conductor wiring, which have become increasingly significant as the transmission rates and frequencies of signals have been further increased, in a printed wiring board formed out of the metal-clad laminate 1.

In addition, even though each insulating film 6 has a first surface 601 and a second surface 602, having mutually different ten-point mean roughness (Rzjis) values, the insulating films 6 may be arranged such that the absolute value of the difference between the ten-point mean roughness (Rzjis) of one surface 401 of the insulating layer 2 and the ten-point mean roughness (Rzjis) of another surface 402 of the insulating layer 2 is equal to or less than 0.35 μm. This enables increasing the peel strength of the sheet of metal foil 3 with respect to the insulating layer 2 to 0.60 N/mm or more. This is presumably because setting the ten-point mean roughness (Rzjis) of the surface 401, in contact with the first sheet of metal foil 31, of the insulating layer 2 at a value either equal to, or approximately equal to, the ten-point mean roughness (Rzjis) of the surface 402, in contact with the second sheet of metal foil 32, of the insulating layer 2 would reduce the chances of causing a time lag between the timing when the insulating layer 2 and the first sheet of metal foil 31 are bonded and the timing when the insulating layer 2 and the second sheet of metal foil 32 are bonded during the manufacturing process of the metal-clad laminate 1. Nevertheless, this theory is only a hypothesis and should not be construed as limiting the scope of this embodiment.

The absolute value of the difference between the ten-point mean roughness (Rzjis) of the one surface 401, in contact with the first sheet of metal foil 31, of the insulating layer 2 and the ten-point mean roughness (Rzjis) of the other surface 402, in contact with the second sheet of metal foil 32, of the insulating layer 2 is preferably equal to or less than 0.25 μm and more preferably equal to or less than 0.15 μm. The absolute value of this difference is particularly preferably equal to zero.

It is also preferable that the absolute value of the difference between the arithmetic mean roughness (Ra) of the one surface 401, in contact with the first sheet of metal foil 31, of the insulating layer 2 and the arithmetic mean roughness (Ra) of the other surface 402, in contact with the second sheet of metal foil 32, of the insulating layer 2 be equal to or less than 0.025 μm. This makes it easier to further increase the peek strength of the sheet of metal foil 3.

The absolute value of the difference between the arithmetic mean roughness (Ra) of the one surface 401, in contact with the first sheet of metal foil 31, of the insulating layer 2 and the arithmetic mean roughness (Ra) of the other surface 402, in contact with the second sheet of metal foil 32, of the insulating layer 2 is more preferably equal to or less than 0.015 μm and is even more preferably equal to or less than 0.005 μm. The absolute value of this difference is particularly preferably equal to zero.

Note that the values of the ten-point mean roughness (Rzjis) and the arithmetic mean roughness (Ra) are obtained based on, for example, the result of measurement on the surface shape of the insulating layer 2 through a confocal laser scanning microscope.

The plurality of insulating films 6 preferably includes at least: a first insulating film 61; and a second insulating film 62 having a greater thickness than the first insulating film 61. Also, in this embodiment, the insulating film 6 having the smaller thickness (e.g., the first insulating film 61) out of the plurality of insulating films 6 that form the insulating layer 2 preferably has a smaller dimension as measured in the width direction. This allows the stress that would cause deformation at end edges of the insulating layer 2 to be absorbed by bending the thicker insulating film 6 in a portion where the thicker insulating film 6 does not overlap with the less thick insulating film 6. Consequently, this may reduce the degree of deformation in the portion where the thicker insulating film 6 (e.g., the second insulating film 62) overlaps with the less thick insulating film 6 (e.g., the first insulating film 61). Therefore, this increases the chances of making the thickness of the metal-clad laminate 1 at the end edges in the width direction varying more gently, thus making it easier to further increase the dimension W₂ as measured in the width direction of a portion usable as a product (i.e., further increase the effective width thereof) of the metal-clad laminate 1. Note that the dimension, as measured in the width direction, of the first insulating film 61 is measured perpendicularly to both the direction in which the first insulating film 61 is transported and the thickness direction with respect to the first insulating film 61. Likewise, the dimension, as measured in the width direction, of the second insulating film 62 is measured perpendicularly to both the direction in which the second insulating film 62 is transported and the thickness direction with respect to the second insulating film 62.

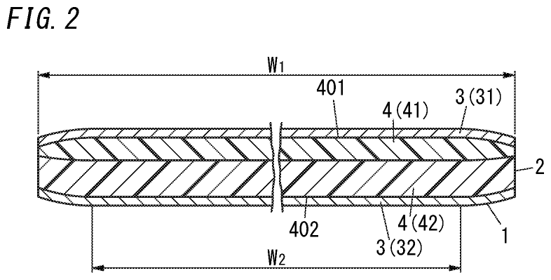

According to this embodiment, an insulating layer 2 is formed out of the plurality of insulating films 6 and sheets of metal foil 3 are stacked on, and bonded to, the insulating layer 2, thereby manufacturing a metal-clad laminate 1 including the insulating layer 2 and the sheets of metal foil 3 laid on top of the insulating layer 2 as shown in FIG. 2. The insulating layer 2 includes a plurality of resin layers 4 derived from the plurality of insulating films 6. In the insulating layer 2, the plurality of resin layers 4 are stacked one on top of another. In other words, the insulating layer 2 includes the plurality of resin layers 4 that are stacked one on top of another. If the insulating films 6 each contains a liquid crystal polymer (i.e., if the insulating films 6 are liquid crystal polymer films), the resin layers 4 each contain the liquid crystal polymer. The manufacturing method according to this embodiment is applicable to manufacturing the metal-clad laminate 1 according to the first embodiment.

In the first embodiment, the insulating films 6 do not have to be liquid crystal polymer films. It is preferable that each insulating film 6 be made of a thermoplastic resin having flexibility. For example, each insulating film 6 may contain at least one resin selected from the group consisting of a liquid crystal polymer, a polyimide resin, a polyethylene terephthalate resin, and a polyethylene naphthalate resin.

In this embodiment, the first insulating film 61 has a smaller dimension as measured in the width direction than the second insulating film 62, thus increasing the chances of making the thickness of the metal-clad laminate 1 at the end edges thereof varying more gently and increasing the effective width of the metal-clad laminate 1. This makes it easier for the metal-clad laminate 1 to achieve a thickness precision less than ±10% or equal to or less than ±7%. These points will be described in further detail later.

A method for manufacturing the metal-clad laminate 1 will be described in detail below.

In this embodiment, two sheets of metal foil 3 are used. One of the two sheets of metal foil 3 will be hereinafter referred to as a “first sheet of metal foil 31” and the other sheet of metal foil 3 will be hereinafter referred to as a “second sheet of metal foil 32.” In this embodiment, not only the first sheet of metal foil 31 and the plurality of insulating films 6 but also the second sheet of metal foil 32 are continuously fed to between the two endless belts 5. A metal-clad laminate 1 is manufactured by stacking the first sheet of metal foil 31, the plurality of insulating films 6, and the second sheet of metal foil 32 in this order one on top of another, and hot-press molding these sheets and films together, between the two endless belts 5.

A manufacturing system for manufacturing the metal-clad laminate 1 will be described with reference to FIG. 1. The manufacturing system includes a double-belt press machine 7. The double-belt press machine 7 includes: two endless belts 5 arranged to face each other; and two hot press devices 10, each of which is provided for an associated one of the two endless belts 5. The endless belts 5 may be made of, for example, stainless steel. Each of these endless belts 5 is wound around two drums 9 and runs around the circumference of the two drums 9 as the drums 9 turn. A stack 11, in which the first sheet of metal foil 31, the plurality of insulating films 6, and the second sheet of metal foil 32 are stacked in this order one on top another, is allowed to pass through the gap between these two endless belts 5. While the stack 11 is passing through the gap between these two endless belts 5, these endless belts 5 may press the stack 11 while making plane contact with one surface of the stack 11 and the opposite surface thereof. The hot press device 10 is provided inside of each of these endless belts 5 and may heat the stack 11 while pressing the stack 11 via the endless belt 5. The hot press device 10 may be, for example, a hydraulic plate configured to hot-press mold the stack 11 via the endless belt 5 with the hydraulic pressure of a heated liquid medium, for example. Alternatively, a plurality of press rollers may be arranged between the two drums 9 such that the hot press device 10 is formed by the two drums 9 and the press rollers. This allows the stack 11 to be heated by, for example, inductively heating the press rollers and the drums 9 and thereby applying heat to the endless belt 5. In addition, this also allows the stack 11 to be pressed by the press rollers via the endless belt 5.

The manufacturing system includes a plurality of feeders 12, each of which holds a lengthy insulating film 6 thereon by winding the insulating film 6 into a roll. In this embodiment, the number of the insulating films 6 provided is only two, namely, the first insulating film 61 and the second insulating film 62. Thus, the feeders 12 include a first feeder 121 for holding the first insulating film 61 and a second feeder 122 for holding the second insulating film 62. In addition, the manufacturing system further includes two more feeders 13 for holding a lengthy first sheet of metal foil 31 and a lengthy second sheet of metal foil 32, respectively, by winding each of the first sheet of metal foil 31 and the second sheet of metal foil 32 into a roll.

The feeders 12 and the feeders 13 may continuously feed the insulating films 6 and the sheets of metal foil 3 (namely, the first sheet of metal foil 31 and the second sheet of metal foil 32), respectively. The manufacturing system further includes a take-up reel 8 for taking up the lengthy metal-clad laminate 1 into a roll. The double-belt press machine 7 is disposed between the feeders 12, the feeders 13, and the take-up reel 8.

When the metal-clad laminate 1 is manufactured, first, the insulating films 6 reeled out from the feeders 12 and the sheets of metal foil 3 reeled out from the feeders 13 are fed to the double-belt press machine 7. At this time, the first sheet of metal foil 31, the plurality of insulating films 6, and the second sheet of metal foil 32 are stacked in this order one on top of another to form a stack 11. Alternatively, when a metal-clad laminate 1 including only one sheet of metal foil 3 is manufactured, the stack 11 may be formed by reeling out the sheet of metal foil 3 from only one of the two feeders 13 and stacking the one sheet of metal foil 3 and the plurality of insulating films 6 in this order one on top of another. The stack 11 is fed to the gap between the two endless belts 5 of the double-belt press machine 7.

In the double-belt press machine 7, the stack 11 passes through the gap between the two endless belts 5 while being sandwiched between the two endless belts 5. The endless belts 5 run around the circumference of the drums 9 at as a high a velocity as the transportation velocity of the insulating films 6 and the sheets of metal foil 3. While moving through the gap between the two endless belts 5, the stack 11 is not only pressed but also heated by the hot press devices 10 via the endless belts 5. This causes the insulating films 6 that have softened or melted to be bonded together to form the insulating layer 2 and also causes the insulating layer 2 and the sheets of metal foil 3 to be bonded together. In this manner, the metal-clad laminate 1 is manufactured and unloaded from the double-belt press machine 7. The metal-clad laminate 1 thus manufactured is then taken up by the take-up reel 8 into a roll.

The highest heating temperature when the stack 11 is hot-press molded may be, for example, equal to or higher than a temperature that is lower by 5° C. than the melting point of the insulating films 6 and equal to or lower than a temperature that is higher by 20° C. than the melting point. Making the highest heating temperature equal to or higher than the temperature that is lower by 5° C. than the melting point causes the insulating films 6 to be softened sufficiently during the hot-press molding, thus enabling increasing the degree of adhesion between the insulating layer 2 and the sheet of metal foil 3 and thereby further increasing the peel strength. Making the highest heating temperature equal to or lower than the temperature that is higher by 20° C. than the melting point may reduce the chances of the insulating films 6 being deformed excessively during the hot-press molding, thus enabling further increasing the dimensional precision. The highest heating temperature may also be equal to or higher than the melting point and equal to or lower than the temperature that is higher by 15° C. than the melting point.

The pressing pressure applied during the hot-press molding may be, for example, equal to or higher than 0.49 MPa and may also be equal to or higher than 2 MPa. This would further increase the peel strength. The pressing pressure may be equal to or lower than 5.9 MPa and may also be equal to or lower than 5 MPa. This would further improve the dimensional precision.

The heating and pressing duration during the hot-press molding may be, for example, equal to or longer than 90 seconds, and may also be equal to or longer than 120 seconds. This would further increase the peel strength. The heating and pressing duration during the hot-press molding may be equal to or shorter than 360 seconds and may also be equal to or shorter than 240 seconds. This would further improve the dimensional precision.

Manufacturing the metal-clad laminate 1 by a method including the double-belt pressing allows the endless belts 5 to press the stack 11 while making plane contact with the stack 11 for a certain period and also facilitates heating the entire stack 11 under the same condition. This reduces the chances of causing a dispersion in heating temperature and pressing pressure and thereby achieves higher peel strength and dimensional precision than heating platen pressing and roll pressing. In addition, this also makes it easier to increase the dimensional stability of the metal-clad laminate 1 when the metal-clad laminate 1 is subjected to an etching process or a heating treatment, for example.

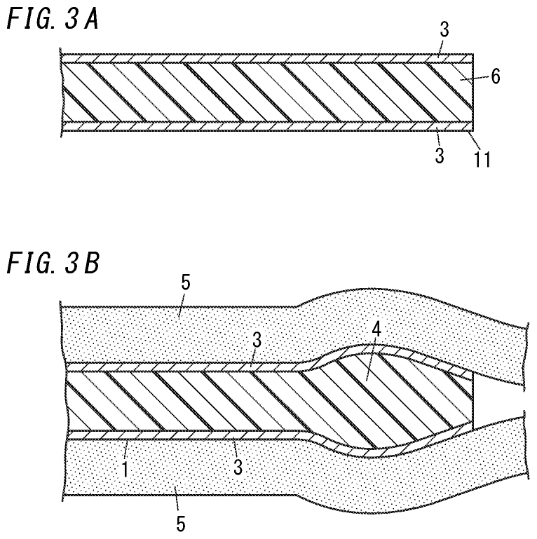

Also, suppose a situation where only a single relatively thick insulating film 6 is used as shown in FIG. 3A when the stack 11 is hot-pressed molded. In that case, as the stack 11 is hot-press molded, the endless belts 5 are likely to be deformed significantly into a winding shape at an end edge portion in the width direction as shown in FIG. 3B. This increases the chances of causing a significant variation in the thickness at the end edge portion of the metal-clad laminate 1 formed out of the stack 11. Consequently, the metal-clad laminate 1 comes to have a decreased effective width. The same statement applies to even a situation where a plurality of insulating films 6 are used and all have the same dimension as measured in the width direction.

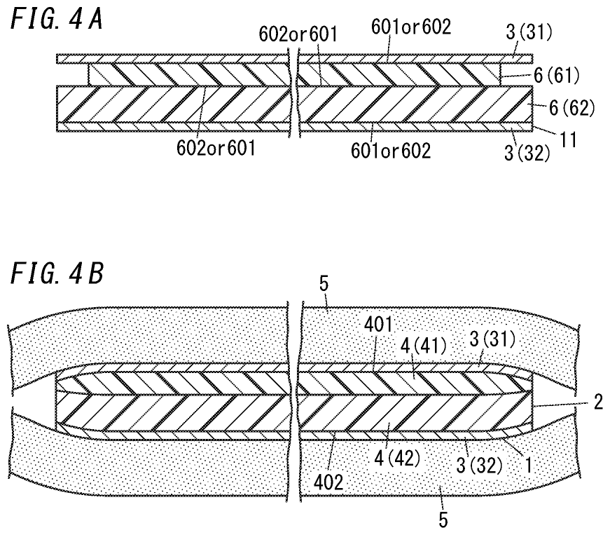

Meanwhile, according to this embodiment, the insulating films 6 preferably include the first insulating film 61 and the second insulating film 62, the first insulating film 61 preferably has a smaller thickness than the second insulating film 62, and the first insulating film 61 preferably has a smaller dimension as measured in the width direction than the second insulating film 62 as described above. In that case, in the stack 11, the second insulating film 62 may be arranged such that both end edges of the second insulating film 62 in the width direction protrude outward with respect to the end edges of the first insulating film 61 as shown in FIG. 4A. In that case, as the stack 11 is hot-press molded, the amount of the resin decreases at both end edges of the metal-clad laminate 1 in the width direction and those end edges tend to be formed to have their thickness decreased toward the outer edges in the width direction. Since the first insulating film 61 has a smaller thickness than the second insulating film 62, the thickness varies gently. This increases the chances of the endless belts 5 being deformed gently along the stack at the end edges of the stack in the width direction. Consequently, the thickness of the metal-clad laminate 1 decreases just slightly at the end edge portions in the width direction as shown in FIG. 4B, and therefore, often comes to have an increased effective width.

In addition, according to this embodiment, even if the stack 11 is hot-press molded, the endless belts 5 are unlikely to be deformed significantly. Thus, even if the peel strength of the sheets of metal foil 3 with respect to the insulating layer 2 is increased in the metal-clad laminate 1 by increasing the pressing pressure, the metal-clad laminate 1 may still easily keep its thickness precision sufficiently high. Thus, this embodiment makes it easier to achieve high thickness precision and high peel strength at the same time. Consequently, this embodiment may achieve a thickness precision less than ±10% or equal to or less than ±7% and a peel strength equal to or greater than 0.60 N/mm at a time.

Each of the plurality of insulating films 6 preferably has a thickness equal to or greater than 45 μm and equal to or less than 120 μm. In that case, a resin layer 40 having a thickness equal to or greater than 45 μm and equal to or less than 120 μm may be formed out of each insulating film 6. Such an insulating film 6 having a thickness equal to or greater than 45 μm and equal to or less than 120 μm may be manufactured easily, and therefore, is readily available and often has a high degree of homogeneity. This increases the chances of the insulating layer 2, formed out of the insulating films 6, having a high degree of homogeneity.

Each of the plurality of insulating films 6 preferably has a dimension equal to or greater than 500 mm and equal to or less than 570 mm as measured in the width direction. As used herein, the “width direction” is perpendicular to both the thickness direction with respect to the insulating films 6 and the direction in which the insulating films 6 and the metal-clad laminate 1 are transported during the manufacturing process of the metal-clad laminate 1. In this case, an insulating layer 2 having a dimension equal to or greater than 500 mm and equal to or less than 570 mm as measured in the width direction may be formed out of the insulating films 6.

The difference in the dimension as measured in the width direction between the first insulating film 61 and the second insulating film 62 is preferably equal to or greater than 10 mm and equal to or less than 70 mm This increases the chance of the thickness varying gently at both end edge portions of the stack 11 in the width direction, thus particularly significantly reducing the chances of the endless belts 5 being deformed and particularly significantly increasing the chances of the metal-clad laminate 1 coming to have an increased effective width. The difference in the dimension as measured in the width direction is more preferably equal to or greater than 10 mm and equal to or less than 50 nm, and even more preferably equal to or greater than 10 mm and equal to or less than 30 mm.

The difference in thickness between the first insulating film 61 and the second insulating film 62 is preferably equal to or greater than 25 μm and equal to or less than 200 μm. This particularly significantly increases the chances of the thickness varying gently at both end edge portions of the stack 11 in the width direction, thus reducing the chances of the endless belts 5 being significantly deformed (into a winding shape, for example) and particularly significantly increasing the chances of the metal-clad laminate 1 coming to have an increased effective width. The difference in thickness is more preferably equal to or greater than 25 μm and equal to or less than 150 μm, and even more preferably equal to or greater than 50 μm and equal to or less than 100 μm.

The number of the insulating films 6 provided is determined according to the thickness of the insulating layer 2 and the respective thicknesses of the insulating films 6 and may be, for example, equal to or greater than two and equal to or less than four.

As described above, each of the plurality of insulating films 6 has a first surface 601 and a second surface 602 having a larger ten-point mean roughness (Rzjis) than the first surface 601. In this case, the ten-point mean roughness (Rzjis) of the first surface 601 may be, for example, equal to or greater than 1.5 μm and equal to or less than 3.0 μm, is preferably equal to or greater than 1.8 μm and equal to or less than 2.7 μm, and is more preferably equal to or greater than 2.0 μm and equal to or less than 2.5 μm. Meanwhile, the ten-point mean roughness (Rzjis) of the second surface 602 may be, for example, equal to or greater than 2.4 μm and equal to or less than 3.3 μm, is preferably equal to or greater than 2.5 μm and equal to or less than 3.1 μm, and is more preferably equal to or greater than 2.6 μm and equal to or less than 3.0 μm. Furthermore, the difference in ten-point mean roughness (Rzjis) between the second surface 602 and the first surface 601 may be, for example, equal to or greater than 0.01 μm and equal to or less than 1.0 μm, is preferably equal to or greater than 0.03 μm and equal to or less than 0.8 μm, and is more preferably equal to or greater than 0.05 μm and equal to or less than 0.6 μm.

The second surface 602 may have a larger arithmetic mean roughness (Ra) than the first surface 601. In that case, the arithmetic mean roughness (Ra) of the first surface 601 may be, for example, equal to or greater than 0.25 μm and equal to or less than 0.45 μm, is preferably equal to or greater than 0.27 μm and equal to or less than 0.40 μm, and is even more preferably equal to or greater than 0.28 μm and equal to or less than 0.35 μm. The arithmetic mean roughness (Ra) of the second surface 602 may be, for example, equal to or greater than 0.27 μm and equal to or less than 0.50 μm, is preferably equal to or greater than 0.28 μm and equal to or less than 0.45 μm, and is even more preferably equal to or greater than 0.30 μm and equal to or less than 0.42 μm. Furthermore, the difference in arithmetic mean roughness (Ra) between the second surface 602 and the first surface 601 may be, for example, greater than 0 μm and equal to or less than 1.0 μm, is preferably equal to or greater than 0.01 μm and equal to or less than 0.8 μm, and is more preferably equal to or greater than 0.05 μm and equal to or less than 0.6 μm.

If each of the plurality of insulating films 6 has the first surface 601 and the second surface 602, then both a surface, in contact with the first sheet of metal foil 31, of an insulating film 6, stacked on the first sheet of metal foil 31, out of the plurality of insulating films 6 and a surface, in contact with the second sheet of metal foil 32, of another insulating film 6, stacked on the second sheet of metal foil 32, out of the plurality of insulating films 6 are preferably either the first surfaces 601 or the second surfaces 602. This particularly significantly reduces the chances of the metal-clad laminate 1 having the stability of its performance undermined. The reason is presumably as follows. Specifically, making, when the metal-clad laminate 1 is manufactured by hot-press molding, for example, the respective surface properties of the surface in contact with the first sheet of metal foil 31 and the surface in contact with the second sheet of metal foil 32 similar to each other makes it easier to substantially equalize, for example, the degree of misalignment between the first sheet of metal foil 31 and the insulating layer 2 and the degree of misalignment between the second sheet of metal foil 32 and the insulating layer 2. In addition, this also makes it easier to apply substantially equal pressure to the surface in contact with the first sheet of metal foil 31 and the second in contact with the second sheet of metal foil 32. This would make it easier to achieve sufficient thickness precision and a high degree of adhesion at the same time.

As described above, the absolute value of the difference between the ten-point mean roughness (Rzjis) of the one surface 401, in contact with the first sheet of metal foil 31, of the insulating layer 2 and the ten-point mean roughness (Rzjis) of the other surface 402, in contact with the second sheet of metal foil 32, of the insulating layer 2 is equal to or less than 0.35 μm. Thus, the absolute value of the difference between the ten-point mean roughness (Rzjis) of the surface, in contact with the first sheet of metal foil 31, of the insulating film 6 in contact with the first sheet of metal foil 31 and the ten-point mean roughness (Rzjis) of the surface, in contact with the second sheet of metal foil 32, of the insulating film 6 in contact with the second sheet of metal foil 32 is preferably equal to or less than 0.35 μm. The absolute value of the difference is more preferably equal to or less than 0.25 μm and even more preferably equal to or less than 0.15 μm. The surface, in contact with the first sheet of metal foil 31, of the insulating film 6 and the surface, in contact with the second sheet of metal foil 32, of the insulating film 6 preferably have the same ten-point mean roughness (Rzjis). This makes it easier to achieve the advantage described above.

The absolute value of the difference in arithmetic mean roughness (Ra) between the surface, in contact with the first sheet of metal foil 31, of the insulating film 6 and the surface, in contact with the second sheet of metal foil 32, of the insulating film 6 is preferably equal to or less than 0.025 μm. The absolute value of the difference is more preferably equal to or less than 0.015 μm and even more preferably equal to or less than 0.005 μm. The surface, in contact with the first sheet of metal foil 31, of the insulating film 6 and the surface, in contact with the second sheet of metal foil 32 of the insulating film 6 preferably have the same arithmetic mean roughness (Ra).

Note that the values of the ten-point mean roughness (Rzjis) and arithmetic mean roughness (Ra) are obtained based on, for example, the result of measurement on the surface shapes of the insulating films 6 through a confocal laser scanning microscope.

Both the surface, in contact with the first sheet of metal foil 31, of the insulating film 6, stacked on the first sheet of metal foil 31, out of the plurality of insulating films 6 and the surface, in contact with the second sheet of metal foil 32, of the other insulating film 6, stacked on the second sheet of metal foil 32, out of the plurality of insulating films 6 are preferably either the first surfaces 601 or the second surfaces 602. This makes it easier to decrease the absolute value of the difference between the roughness of the surface 401, in contact with the first sheet of metal foil 31, of the insulating layer 2 and the roughness of the surface 402, in contact with the second sheet of metal foil 32, of the insulating layer 2.

In the metal-clad laminate 1 manufactured according to the first embodiment, the sheet of metal foil 3 preferably has a peel strength equal to or greater than 0.60 N/mm with respect to the insulating layer 2. The sheet of metal foil 3 more preferably has a peel strength equal to or greater than 0.8 N/mm, even more preferably has a peel strength equal to or greater than 0.9 N/mm, and particularly preferably has a peel strength equal to or greater than 1.0 N/mm

Next, a metal-clad laminate 1 according to a second embodiment will be described. As shown in FIG. 2, the metal-clad laminate 1 includes an insulating layer 2 and at least one sheet of metal foil 3 laid on top of the insulating layer 2. The metal-clad laminate 1 may include two sheets of metal foil 3. In that case, the two sheets of metal foil 3 are respectively stacked on one surface 401 and the opposite surface 402 of the insulating layer 2 as shown in FIG. 2. In the following description, one of the two sheets of metal foil 3 will be hereinafter referred to as a “first sheet of metal foil 31” and the other sheet of metal foil 3 will be hereinafter referred to as a “second sheet of metal foil 32.” That is to say, the first sheet of metal foil 31, the insulating layer 2, and the second sheet of metal foil 32 are stacked in this order one on top of another.

The insulating layer 2 includes a plurality of resin layers 4 which are stacked one on top of another. In other words, the insulating layer 2 is formed by stacking the plurality of resin layers 40 one on top of another. Each resin layer 4 may be made of, for example, a thermoplastic resin having flexibility. For example, each resin layer 4 may contain at least one resin selected from the group consisting of a liquid crystal polymer, a polyimide resin, a polyethylene terephthalate resin, and a polyethylene naphthalate resin. Each resin layer 40 preferably contains a liquid crystal polymer. The insulating layer 2 has a thickness equal to or greater than 100 μm and equal to or less than 300 μm. Furthermore, the sheet of metal foil 3 has a peel strength equal to or greater than 0.60 N/mm with respect to the insulating layer 2.

According to this embodiment, the insulating layer 2 is made up of the plurality of resin layers 4, thus making it easier to increase the thickness of the insulating layer 2. Thickening the insulating layer 2 may reduce the chances of transmission loss being caused by electrostatic capacitance and leaking resistance between respective parts of conductor wiring, which have become increasingly significant as the transmission rates and frequencies of signals have been further increased, in a printed wiring board formed out of the metal-clad laminate 1. In addition, making the insulating layer 2 up of the plurality of resin layers 4 and setting the peel strength of the sheet of metal foil 3 at 0.60 N/mm or more as described above also reduces the chances of causing a decline in the performance of the metal-clad laminate 1.

This metal-clad laminate 1 may be used to transmit an RF signal. For example, this metal-clad laminate 1 may be used to manufacture a printed wiring board. In addition, the metal-clad laminate 1 may also be used to make a flat cable.

A configuration for the insulating layer 2 in the metal-clad laminate 1 will be described in further detail.

As described above, the insulating layer 2 has a thickness equal to or greater than 100 μm and equal to or less than 300 μm. Making the thickness of the insulating layer 2 equal to or greater than 100 μm increases the chances of the metal-clad laminate 1 exhibiting good RF characteristics. Also, making the thickness of the insulating layer 2 equal to or less than 300 μm makes it easier to manufacture the metal-clad laminate 1 with good stability by hot-press molding and to allow the metal-clad laminate 1 to exhibit stabilized characteristics. The insulating layer 2 more preferably has a thickness equal to or greater than 100 μm and equal to or less than 250 μm and even more preferably has a thickness equal to or greater than 100 μm and equal to or less than 200 μm.

As described above, the insulating layer 2 includes a plurality of resin layers 4 which are stacked one on top of another. Each resin layer 4 preferably contains a liquid crystal polymer as described above. Examples of the liquid crystal polymer include a polycondensate of ethylene terephthalate and parahydroxybenzoic acid, a polycondensate of phenol, phthalic acid, and parahydroxybenzoic acid, and a polycondensate of 2,6-hydroxynaphthoic acid and parahydroxybenzoic acid. The liquid crystal polymer may be selected from commercially available products. Specific examples of the liquid crystal polymer include Vecstar CTQ and Vecstar CTZ manufactured by Kuraray Co., Ltd.

Each of the plurality of resin layers 4 preferably has a thickness equal to or greater than 45 μm and equal to or less than 120 μm. In that case, each resin layer 4 may be formed out of an insulating film 6 having a thickness equal to or greater than 45 μm and equal to or less than 120 pm. An insulating film 6 having such a thickness may be manufactured easily, and therefore, is readily available and often has a high degree of homogeneity. This increases the chances of the insulating layer 2 having a high degree of homogeneity. The thickness is more preferably equal to or greater than 50 μm and equal to or less than 100 μm.

The number of the resin layers 4 included in the insulating layer 2 is determined according to the thickness of the insulating layer 2 and the respective thicknesses of the resin layers 4 and may be, for example, equal to or greater than two and equal to or less than four.

The plurality of resin layers 4 that form the insulating layer 2 preferably includes at least two resin layers 4 having mutually different thicknesses. In FIG. 2, the resin layers 4 include a first resin layer 41 and a second resin layer 42 which is stacked directly in contact with the first resin layer 41 and which has a greater thickness than the first resin layer 41. The metal-clad laminate 1 usually tends to cause a variation in thickness at end edge portions in the width direction. Thus, in general, the metal-clad laminate 1 tends to have a gradually decreasing thickness at the end edge portions thereof as shown in FIG. 2. Nevertheless, an insulating layer 2 including at least two resin layers 4 with mutually different thicknesses is less likely to cause a variation in thickness at the end edge portions thereof than an insulating layer 2 formed by using only resin layers 4 each having the same thickness. Comparing the insulating layer 2 including a plurality of resin layers 4 with mutually different thicknesses with the insulating layer 2 including a plurality of resin layers 4 each having the same thickness on the supposition that these two insulating layers 2 have the same thickness, the former insulating layer 2 is less likely to cause a variation in its thickness. This is because at each end edge portion of the insulating layer 2 including a plurality of (e.g., two) resin layers 4 with mutually different thicknesses, the thicker one of the resin layers 4 is less likely to be deformed than the other less thick one of the resin layers 4. This reduces the chances of causing a dispersion in thickness at the end edge portions of the metal-clad laminate 1 in the width direction, thus making it easier for the metal-clad laminate 1 to have an increased dimension W₂ (i.e., an effective width) in a portion thereof usable as a product. In addition, this may also reduce the chances of causing inconveniences due to the deformation of the metal-clad laminate 1 such as formation of wavy unevenness and bending at the end edge portions thereof. As used herein, the “width direction” with respect to the metal-clad laminate 1 and the “width direction” with respect to the insulating layer 2 are perpendicular to both the thickness direction and longitudinal direction with respect to the insulating layer 2. Also, if the metal-clad laminate 1 is manufactured by a continuous process, then the “width direction” is perpendicular to both the thickness direction with respect to the insulating layer 2 and the direction in which the metal-clad laminate 1 is transported during the manufacturing process of the metal-clad laminate 1.

The plurality of resin layers 4 particularly preferably includes at least two resin layers 4, of which the difference in thickness is equal to or greater than 25 μm and equal to or less than 100 μm. For example, in the example illustrated in FIG. 2, the thickness of the second resin layer 42 is preferably larger than the thickness of the first resin layer 41 by a difference that is equal to or greater than 25 μm and equal to or less than 100 μm. This difference in thickness is more preferably equal to or greater than 25 μm and equal to or less than 75 μm and is even more preferably equal to or greater than 25 μm and equal to or less than 50 μm.

The dimension W₁, as measured in the width direction, of the insulating layer 2 is preferably equal to or greater than 500 mm and equal to or less than 570 mm. Making the dimension as measured in the width direction equal to or greater than 500 mm and equal to or less than 570 mm makes it easier, particularly when the metal-clad laminate 1 is manufactured by performing hot-press molding at a temperature around the melting point of the resin layers 4, to shift any end edge portion of the insulating layer 2, of which the thickness has varied in the width direction, toward the outer edge. This makes it easier to have such a portion with the varied thickness located outside of a portion, actually used as a product, of the metal-clad laminate 1. In addition, this also makes it easier to manufacture a product, of which the width meets the standard width of 250 mm, by cutting off the metal-clad laminate 1.

The metal-clad laminate 1 may be wound into a roll. This allows the metal-clad laminate 1 to be used for manufacturing a printed wiring board, for example, by unwinding the roll of the metal-clad laminate 1.

The metal-clad laminate 1 preferably has a thickness precision less than ±10%. That is to say, the absolute value of the difference between the average thickness and maximum thickness of the metal-clad laminate 1 is preferably less than 10% of the average thickness and the absolute value of the difference between the average thickness and minimum thickness of the metal-clad laminate 1 is also preferably less than 10% of the average thickness. The average thickness, maximum thickness, and minimum thickness of the metal-clad laminate 1 are determined in the following manner. Specifically, the respective thicknesses of six portions, which are arranged at regular intervals in the width direction, of the metal-clad laminate 1 are measured with a micrometer. Those six portions consist of two end edge portions of the metal-clad laminate 1 and four portions located between these two end edges portions. The average value of the six measured values thus obtained may be regarded as an average thickness. The maximum value of the six measured values is defined to be a maximum thickness and the minimum value thereof is defined to be a minimum thickness. The thickness precision is more preferably equal to or less than ±7%.

If the thickness of the metal-clad laminate 1 varies at both end edge portions in the width direction, then the thickness precision described above may be achieved by cutting off those end edge portions. As described above, this embodiment makes it easier to shift, toward the outer edge, any end edge portion of the insulating layer 2, of which the thickness has varied in the width direction, in the metal-clad laminate 1. This makes it easier to increase the dimension as measured in the width direction (i.e., the effective width) of a portion, usable as a product, of the metal-clad laminate 1. In other words, this makes it easier to reduce the width of such an end edge portion with the varied thickness of the metal-clad laminate 1. Consequently, the thickness precision described above is achieved by cutting off a portion with a reduced width from the metal-clad laminate 1.

Furthermore, as described above, the peel strength of the sheet of metal foil 3 with respect to the insulating layer 2 is equal to or greater than 0.60 N/mm in the metal-clad laminate 1. This allows the metal-clad laminate 1 to exhibit stabilized performance The peel strength of the sheet of metal foil 3 is more preferably equal to or greater than 0.8 N/mm, even more preferably equal to or greater than 0.9 N/mm, and particularly preferably equal to or greater than 1.0 N/mm Note that the peel strength of the sheet of metal foil 3 is the average value of peel strengths of the sheet of metal foil 3 that were measured at eight points on the metal-clad laminate 1 by 90-degree peeling method using an autograph.

The metal-clad laminate 1 according to the second embodiment may be manufactured by the manufacturing method according to the first embodiment. Alternatively, the metal-clad laminate 1 according to the second embodiment may also be manufactured by any method other than the manufacturing method according to the first embodiment.

A printed wiring board such as a flexible printed wiring board may be formed out of each of the metal-clad laminate 1 manufactured by the manufacturing method according to the first embodiment and the metal-clad laminate 1 according to the second embodiment. For example, a printed wiring board may be manufactured by patterning the sheet of metal foil 3 of the metal-clad laminate 1 by photolithographic process or any other suitable process into the shape of conductor wiring. Also, a multilayer printed wiring board may also be manufactured by stacking a plurality of such printed wiring boards one on top of another by a known method. Alternatively, a flex-rigid printed wiring board may also be manufactured by partially stacking a plurality of printed wiring boards one on top of another by a known method. Furthermore, a flat cable may also be formed out of each of the metal-clad laminate 1 manufactured by the manufacturing method according to the first embodiment and the metal-clad laminate 1 according to the second embodiment.

### EXAMPLES

Next, more specific examples of the first and second embodiments will be described. Note that the following are only examples of the first and second embodiments and should not be construed as limiting.

1. Manufacturing of Metal-Clad Laminate

Materials for a metal-clad laminate as shown in the following Tables 1 and 2 were provided. Note that CTQ in the “Type of material” column for the first insulating film, the second insulating film, the third insulating film, and the fourth insulating film refers to Vecstar CTQ manufactured by Kuraray Co., Ltd. The first surface of each of the first insulating film, the second insulating film, the third insulating film, and the fourth insulating film had a ten-point mean roughness (Rzjis) of 2.3 μm and an arithmetic mean roughness (Ra) of 0.30 μm. The second surface thereof had a ten-point mean roughness (Rzjis) of 2.7 μm and an arithmetic mean roughness (Ra) of 0.33 μm. Also, TP4-S in the “Type of material” column for the first sheet of metal foil and the second sheet of metal foil refers to a sheet of copper foil (product number TP4-S) manufactured by Fukuda Metal Foil & Powder Co., Ltd. The difference in dimension as measured in the width direction between the first insulating film and the second insulating film is shown in Tables 1 and 2.

In the first to ninth examples and the first to eighth comparative examples, a hot-press molding process was conducted by hot-press molding a stack in which the first sheet of metal foil, the first insulating film, the second insulating film, and the second sheet of metal foil were stacked in this order one on top of another. In the tenth example, a hot-press molding process was conducted by hot-press molding a stack in which the first sheet of metal foil, the first insulating film, the second insulating film, and the third insulating film were stacked in this order one on top of another. In the eleventh example, a hot-press molding process was conducted by hot-press molding a stack in which the first sheet of metal foil, the fourth insulating film, the first insulating film, the second insulating film, and the third insulating film were stacked in this order one on top of another. The hot-press molding methods, the highest heating temperatures, the pressing pressures, and the heating and pressing durations in the respective examples and comparative examples are also shown in the following Tables 1 and 2. In addition, the following Tables 1 and 2 also show whether the surface, in contact with the first sheet of metal foil, of the first insulating film is the first surface or the second surface and whether the surface, in contact with the second sheet of metal foil, of the second insulating film is the first surface or the second surface.

2. Evaluation Tests

The metal-clad laminate was subjected to the following evaluation tests. The results are summarized in the following Tables 1 and 2.

2.1. Effective Width

The thickness of the metal-clad laminate was measured with a micrometer with the measuring spot moved in the width direction, thereby checking the variation in the thickness of the metal-clad laminate in the width direction. The dimension as measured in the width direction of a portion having a thickness variation within ±10% and including a middle portion of the metal-clad laminate was defined to be an effective width. As used herein, the “thickness variation” refers to the variation ratio of the thickness measured in a non-middle portion to the thickness measured in the middle portion. As the thickness variation, the average value of respective thicknesses measured at six non-middle portions was calculated.

2.2. Thickness Precision

In the metal-clad laminate, the respective thicknesses of six portions, each having a thickness variation within ±10%, including the middle portion of the metal-clad laminate, and arranged at regular intervals in the width direction, were measured with a micrometer. These six portions included two end edge portions of the metal-clad laminate and four portions located between the two end edge portions. The average value of the six measured values thus obtained was defined to be an average thickness, the maximum value of the six measured values was defined to be a maximum thickness, and the minimum value of the six measured values was defined to be a minimum thickness. A thickness precision was calculated based on these results of measurement.

2.3. Peel Strength

The sheet of metal foil of the metal-clad laminate was subjected to an etching process, thereby forming a linear wire having dimensions of 1 mm×200 mm The peel strength of this wire with respect to the insulating layer was measured by 90-degree peeling method. Such measurement was carried out in the same way eight times and an arithmetic mean of the results was calculated. As for the sixth example, the measured values varied significantly and were about 0.9 N/mm and about 1.9 N/mm more often than not, and therefore, were evaluated to be “0.9-1.9.”

2.4. Film Interface

The metal-clad laminate was cut off and a cross section of the insulating layer was observed through an optical microscope, thereby determining whether or not any interface was recognized between two adjacent resin layers in the insulating layer. If any interface was recognized there, the answer was YES. If no interfaces were recognized there, the answer was NO.

2.5. Dimensional Stability During Etching Process

The dimensional stability of the metal-clad laminate during the etching process was evaluated in the following manner in compliance with the IPC-TM650 2.2.4. Specifically, a test sample having dimensions of 250 mm×250 mm in plan view was formed by cutting off the metal-clad laminate. Four holes were opened through this test sample for the purpose of dimensional measurement. The intervals in the width direction and in the transporting direction between these holes of the test sample were measured. Subsequently, the sheet of metal foil of the test sample was removed entirely by etching process to obtain an unclad plate. The intervals in the width direction and in the transporting direction between the holes of the unclad plate were measured. Based on these results, the variation ratios in the dimension as measured in the width direction and the dimension as measured in the transporting direction were calculated.

2.6. Dimensional Stability During Heating Treatment

A test sample was formed as described in the “2.5. Dimensional stability during etching process” section. The intervals in the width direction and in the transporting direction between the holes of this test sample were measured. Subsequently, the test sample was heated under the condition including a heating temperature of 150° C. and a heating duration of 30 minutes. Next, the intervals in the width direction and in the transporting direction were measured with respect to the test sample. Based on these results, the variation ratios in the dimension as measured in the width direction and the dimension as measured in the transporting direction were calculated.

TABLE 1

| | | Examples | | | | | | | | | | |
|---|---|---|---|---|---|---|---|---|---|---|---|---|
| | | 1 | 2 | 3 | 4 | 5 | 6 | 7 | 8 | 9 | 10 | 11 |
| First | Type of material | CTQ | CTQ | CTQ | CTQ | CTQ | CTQ | CTQ | CTQ | CTQ | CTQ | CTQ |
| insulating | Melting point (° C.) | 310 | 310 | 310 | 310 | 310 | 310 | 310 | 310 | 310 | 310 | 310 |
| film | Thickness (μm) | 75 | 75 | 50 | 50 | 50 | 75 | 50 | 50 | 100 | 50 | 50 |
| | Width (mm) | 555 | 555 | 555 | 530 | 530 | 555 | 530 | 530 | 555 | 555 | 555 |
| Second | Type of material | CTQ | CTQ | CTQ | CTQ | CTQ | CTQ | CTQ | CTQ | CTQ | CTQ | CTQ |
| insulating | Melting point (° C.) | 310 | 310 | 310 | 310 | 310 | 310 | 310 | 310 | 310 | 310 | 310 |
| film | Thickness (μm) | 75 | 75 | 100 | 100 | 100 | 75 | 100 | 75 | 100 | 50 | 50 |
| | Width (mm) | 555 | 555 | 555 | 555 | 555 | 555 | 555 | 555 | 555 | 555 | 555 |
| | Difference in width (mm) | 0 | 0 | 0 | 25 | 25 | 0 | 25 | 25 | 0 | 0 | 0 |
| Third | Type of material | — | — | — | — | — | — | — | — | — | CTQ | CTQ |
| insulating | Melting point (° C.) | — | — | — | — | — | — | — | — | — | 310 | 310 |
| film | Thickness (μm) | — | — | — | — | — | — | — | — | — | 50 | 50 |
| | Width (mm) | — | — | — | — | — | — | — | — | — | 555 | 555 |
| Fourth | Type of material | — | — | — | — | — | — | — | — | — | — | CTQ |
| insulating | Melting point (° C.) | — | — | — | — | — | — | — | — | — | — | 310 |
| film | Thickness (μm) | — | — | — | — | — | — | — | — | — | — | 50 |
| | Width (mm) | — | — | — | — | — | — | — | — | — | — | 555 |
| Total thickness (μm) of insulating layer | | 150 | 150 | 150 | 150 | 150 | 150 | 150 | 125 | 200 | 150 | 200 |
| Insulating film's surface in contact | | 1st | 2nd | 1st | 1st | 2nd | 1st | 1st | 1st | 1st | 1st | 1st |
| with first sheet of metal foil | | | | | | | | | | | | |
| Insulating film's surface in contact | | 1st | 2nd | 1st | 1st | 2nd | 1st | 1st | 1st | 1st | 1st | 1st |
| with second sheet of metal foil | | | | | | | | | | | | |
| First sheet of | Type of material | TP4-S | TP4-S | TP4-S | TP4-S | TP4-S | TP4-S | TP4-S | TP4-S | TP4-S | TP4-S | TP4-S |
| metal foil | Thickness (μm) | 12 | 12 | 12 | 12 | 12 | 12 | 12 | 12 | 12 | 12 | 12 |
| First sheet of | Type of material | TP4-S | TP4-S | TP4-S | TP4-S | TP4-S | TP4-S | TP4-S | TP4-S | TP4-S | TP4-S | TP4-S |
| metal foil | Thickness (μm) | 12 | 12 | 12 | 12 | 12 | 12 | 12 | 12 | 12 | 12 | 12 |
| Molding | Method | Double | Double | Double | Double | Double | Double | Double | Double | Double | Double | Double |
| condition | | belt | belt | belt | belt | belt | belt | belt | belt | belt | belt | belt |
| | | press | press | press | press | press | press | press | press | press | press | press |
| | Highest heating | 320 | 320 | 320 | 320 | 320 | 360 | 320 | 320 | 320 | 320 | 320 |
| | temperature (° C.) | | | | | | | | | | | |
| | Pressing pressure (MPa) | 3.5 | 3.5 | 3.5 | 3.5 | 3.5 | 3.5 | 3.5 | 3.5 | 3.5 | 3.5 | 3.5 |
| | Heating and pressing | 150 | 150 | 150 | 150 | 150 | 150 | 150 | 150 | 150 | 150 | 150 |
| | duration (s) | | | | | | | | | | | |
| Evaluation | Thickness precision | ±5% | ±5% | ±5% | ±5% | ±5% | ±8% | ±5% | ±5% | ±5% | ±5% | ±5% |
| | Effective width (mm) | 504 | 504 | 504 | 510 | 510 | 500 | 509 | 511 | 491 | 492 | 483 |
| | Peel strength (N/mm) | 0.80 | 0.75 | 0.80 | 0.80 | 0.75 | 0.9-1.9 | 0.60 | 0.60 | 0.70 | 0.70 | 0.70 |
| | Film interface | YES | YES | YES | YES | YES | NO | YES | YES | YES | YES | YES |
| | Dimensional stability | 0.035 | 0.022 | 0.037 | 0.035 | 0.022 | −0.098 | 0.030 | 0.042 | 0.008 | 0.052 | 0.043 |
| | during etching | | | | | | | | | | | |
| | (transporting direction) | | | | | | | | | | | |
| | Dimensional stability | −0.001 | 0.014 | 0.006 | −0.001 | 0.014 | −0.155 | 0.010 | 0.020 | 0.021 | 0.011 | −0.001 |
| | during etching | | | | | | | | | | | |
| | (width direction) | | | | | | | | | | | |
| | Dimensional stability | 0.092 | 0.088 | 0.092 | 0.092 | 0.088 | −0.148 | 0.082 | 0.103 | 0.041 | 0.117 | 0.110 |
| | during heating | | | | | | | | | | | |
| | (transporting direction) | | | | | | | | | | | |
| | Dimensional stability | 0.032 | 0.046 | 0.066 | 0.032 | 0.046 | −0.254 | 0.076 | 0.059 | 0.041 | 0.047 | 0.068 |
| | during heating | | | | | | | | | | | |
| | (width direction) | | | | | | | | | | | |

TABLE 2

| | | Comparative Examples | | | | | | | |
|---|---|---|---|---|---|---|---|---|---|
| | | 1 | 2 | 3 | 4 | 5 | 6 | 7 | 8 |
| First | Type of material | CTQ | CTQ | CTQ | CTQ | CTQ | CTQ | CTQ | CTQ |
| insulating | Melting point (° C.) | 310 | 310 | 310 | 310 | 310 | 310 | 310 | 310 |
| film | Thickness (μm) | 75 | 75 | 75 | 75 | 75 | 50 | 50 | 50 |
| | Width (mm) | 555 | 555 | 555 | 555 | 555 | 555 | 555 | 555 |
| Second | Type of material | CTQ | CTQ | CTQ | CTQ | CTQ | CTQ | CTQ | CTQ |
| insulating | Melting point (° C.) | 310 | 310 | 310 | 310 | 310 | 310 | 310 | 310 |
| film | Thickness (μm) | 75 | 75 | 75 | 75 | 75 | 100 | 100 | 100 |
| | Width (mm) | 555 | 555 | 555 | 555 | 555 | 555 | 555 | 555 |
| | Difference in width (mm) | 0 | 0 | 0 | 0 | 0 | 0 | 0 | 0 |
| Third | Type of material | — | — | — | — | — | — | — | — |
| insulating | Melting point (° C.) | — | — | — | — | — | — | — | — |
| film | Thickness (μm) | — | — | — | — | — | — | — | — |
| | Width (mm) | — | — | — | — | — | — | — | — |
| Fourth | Type of material | — | — | — | — | — | — | — | — |
| insulating | Melting point (° C.) | — | — | — | — | — | — | — | — |
| film | Thickness (μm) | — | — | — | — | — | — | — | — |
| | Width (mm) | — | — | — | — | — | — | — | — |
| Total thickness (μm) of insulating layer | | 150 | 150 | 150 | 150 | 150 | 150 | 150 | 150 |
| Insulating film's surface in contact | | 2nd | 1st | 1st | 1st | 1st | 1st | 1st | 1st |
| with first sheet of metal foil | | | | | | | | | |
| Insulating film's surface in contact | | 1st | 2nd | 2nd | 2nd | 2nd | 2nd | 2nd | 2nd |
| with second sheet of metal foil | | | | | | | | | |
| First sheet of | Type of material | TP4-S | TP4-S | TP4-S | TP4-S | TP4-S | TP4-S | TP4-S | TP4-S |
| metal foil | Thickness (μm) | 12 | 12 | 12 | 12 | 12 | 12 | 12 | 12 |
| First sheet of | Type of material | TP4-S | TP4-S | TP4-S | TP4-S | TP4-S | TP4-S | TP4-S | TP4-S |
| metal foil | Thickness (μm) | 12 | 12 | 12 | 12 | 12 | 12 | 12 | 12 |
| Molding | Method | Double | Double | Double | Double | Double | Double | Double | Double |
| condition | | belt | belt | belt | belt | belt | belt | belt | belt |
| | | press | press | press | press | press | press | press | press |
| | Highest heating | 320 | 320 | 330 | 325 | 320 | 330 | 325 | 320 |
| | temperature (° C.) | | | | | | | | |
| | Pressing pressure (MPa) | 3.5 | 3.5 | 3.5 | 3.5 | 3.5 | 3.5 | 3.5 | 3.5 |
| | Heating and pressing | 150 | 150 | 150 | 150 | 150 | 150 | 150 | 150 |
| | duration (s) | | | | | | | | |
| | Thickness precision | ±5% | ±5% | ±5% | ±5% | ±5% | ±5% | ±5% | ±5% |
| Evaluation | Effective width (mm) | 496 | 496 | 495 | 496 | 495 | 498 | 498 | 498 |
| | Peel strength (N/mm) | 0.41 | 0.38 | 0.55 | 0.54 | 0.44 | 0.55 | 0.54 | 0.44 |
| | Film interface | YES | YES | YES | YES | YES | YES | YES | YES |
| | Dimensional stability | 0.022 | 0.022 | 0.022 | 0.032 | 0.029 | 0.031 | 0.030 | 0.031 |
| | during etching | | | | | | | | |
| | (transporting direction) | | | | | | | | |
| | Dimensional stability | 0.014 | 0.014 | 0.013 | 0.020 | 0.019 | 0.022 | 0.009 | 0.014 |
| | during etching | | | | | | | | |
| | (width direction) | | | | | | | | |
| | Dimensional stability | 0.088 | 0.088 | 0.090 | 0.080 | 0.084 | 0.086 | 0.089 | 0.092 |
| | during heating | | | | | | | | |
| | (transporting direction) | | | | | | | | |
| | Dimensional stability | 0.046 | 0.046 | 0.044 | 0.040 | 0.043 | 0.044 | 0.060 | 0.058 |
| | during heating | | | | | | | | |
| | (width direction) | | | | | | | | |

1. A method for manufacturing a metal-clad laminate, the method comprising:
continuously feeding, to between two endless belts, a first sheet of metal foil, a plurality of insulating films, and a second sheet of metal foil different from the first sheet of metal foil; and
stacking, between the endless belts, the first sheet of metal foil, the plurality of insulating films, and the second sheet of metal foil in this order one on top of another and hot-press molding the first sheet of metal foil, the plurality of insulating films, and the second sheet of metal foil together to form an insulating layer out of the plurality of insulating films,
each of the plurality of insulating films having a first surface and a second surface opposite from the first surface, the second surface having a larger ten-point mean roughness Rzjis than the first surface,
the absolute value of difference between a ten-point mean roughness Rzjis of a surface, in contact with the first sheet of metal foil, of the insulating layer and a ten-point mean roughness Rzjis of another surface, in contact with the second sheet of metal foil, of the insulating layer being equal to or less than 0.35 μm.

2. The method of claim 1, wherein
the absolute value of difference between an arithmetic mean roughness Ra of the surface, in contact with the first sheet of metal foil, of the insulating layer and an arithmetic mean roughness Ra of the other surface, in contact with the second sheet of metal foil, of the insulating layer is equal to or less than 0.025 μm.

3. The method of claim 1, wherein
both a surface, in contact with the first sheet of metal foil, of an insulating film, stacked on the first sheet of metal foil, out of the plurality of insulating films and a surface, in contact with the second sheet of metal foil, of another insulating film, stacked on the second sheet of metal foil, out of the plurality of insulating films are either the first surfaces or the second surfaces.

4. The method of claim 1, wherein
the plurality of insulating films includes: at least a first insulating film; and a second insulating film having a greater thickness than the first insulating film,
a dimension, as measured in a width direction, of the first insulating film is smaller than a dimension, as measured in a width direction, of the second insulating film,
the width direction with respect to the first insulating film is perpendicular to both a direction in which the first insulating film is transported and a thickness direction with respect to the first insulating film, and
the width direction with respect to the second insulating film is perpendicular to both a direction in which the second insulating film is transported and a thickness direction with respect to the second insulating film.

5. The method of claim 4, wherein
a difference between the dimension, as measured in the width direction, of the first insulating film and the dimension, as measured in the width direction, of the second insulating film is equal to or greater than 10 mm and equal to or less than 30 mm.

6. The method of claim 1, wherein
a sum of respective thicknesses of the plurality of insulating films is equal to or greater than 100 μm and equal to or less than 300 μm.

7. The method of claim 1, wherein
the insulating films each contain a liquid crystal polymer.

8. A metal-clad laminate comprising:
an insulating layer; and
a sheet of metal foil laid on top of the insulating layer,
the insulating layer including a plurality of resin layers,
the insulating layer having a thickness equal to or greater than 100 μm and equal to or less than 300 μm,
the resin layers each containing a liquid crystal polymer,
a peel strength of the sheet of metal foil with respect to the insulating layer being equal to or greater than 0.60 N/mm.

9. The metal-clad laminate of claim 8, wherein
the metal-clad laminate has a thickness precision less than ±10%.

10. The metal-clad laminate of claim 8, wherein
each of the plurality of resin layers has a thickness equal to or greater than 45 μm and equal to or less than 120 μm.

11. The metal-clad laminate of claim 8, wherein
the plurality of resin layers includes at least two resin layers having mutually different thicknesses.

12. The metal-clad laminate of claim 8, wherein
a dimension, as measured in a width direction, of the insulating layer is equal to or greater than 500 mm and equal to or less than 570 mm, and
the width direction with respect to the insulating layer is perpendicular to both a thickness direction and a longitudinal direction with respect to the insulating layer.

13. The metal-clad laminate of claim 8, wherein
the metal-clad laminate is wound into a roll.

14. The method of claim 2, wherein
both a surface, in contact with the first sheet of metal foil, of an insulating film, stacked on the first sheet of metal foil, out of the plurality of insulating films and a surface, in contact with the second sheet of metal foil, of another insulating film, stacked on the second sheet of metal foil, out of the plurality of insulating films are either the first surfaces or the second surfaces.

15. The method of claim 2, wherein
the plurality of insulating films includes: at least a first insulating film; and a second insulating film having a greater thickness than the first insulating film,
a dimension, as measured in a width direction, of the first insulating film is smaller than a dimension, as measured in a width direction, of the second insulating film,
the width direction with respect to the first insulating film is perpendicular to both a direction in which the first insulating film is transported and a thickness direction with respect to the first insulating film, and
the width direction with respect to the second insulating film is perpendicular to both a direction in which the second insulating film is transported and a thickness direction with respect to the second insulating film.

16. The method of claim 3, wherein
the plurality of insulating films includes: at least a first insulating film; and a second insulating film having a greater thickness than the first insulating film,
a dimension, as measured in a width direction, of the first insulating film is smaller than a dimension, as measured in a width direction, of the second insulating film,
the width direction with respect to the first insulating film is perpendicular to both a direction in which the first insulating film is transported and a thickness direction with respect to the first insulating film, and
the width direction with respect to the second insulating film is perpendicular to both a direction in which the second insulating film is transported and a thickness direction with respect to the second insulating film.

17. The method of claim 14, wherein
the plurality of insulating films includes: at least a first insulating film; and a second insulating film having a greater thickness than the first insulating film,
a dimension, as measured in a width direction, of the first insulating film is smaller than a dimension, as measured in a width direction, of the second insulating film,
the width direction with respect to the first insulating film is perpendicular to both a direction in which the first insulating film is transported and a thickness direction with respect to the first insulating film, and
the width direction with respect to the second insulating film is perpendicular to both a direction in which the second insulating film is transported and a thickness direction with respect to the second insulating film.

18. The method of claim 15, wherein
a difference between the dimension, as measured in the width direction, of the first insulating film and the dimension, as measured in the width direction, of the second insulating film is equal to or greater than 10 mm and equal to or less than 30 mm.

19. The method of claim 16, wherein
a difference between the dimension, as measured in the width direction, of the first insulating film and the dimension, as measured in the width direction, of the second insulating film is equal to or greater than 10 mm and equal to or less than 30 mm.

20. The method of claim 17, wherein
a difference between the dimension, as measured in the width direction, of the first insulating film and the dimension, as measured in the width direction, of the second insulating film is equal to or greater than 10 mm and equal to or less than 30 mm.
